(19) United States
(12) Patent Application Publication
(10) Pub. No.: US 2026/0040987 A1
(43) Pub. Date: Feb. 5, 2026

(54) METHODS AND STRUCTURE FOR HYBRID BONDING

(71) Applicant: ASM IP Holding B.V., Almere (NL)

(72) Inventors: Tony Ping-Chen Chiang, Los Gatos, CA (US); Avinash Shantaram, Scottsdale, AZ (US); Joy Watanabe, Campbell, CA (US); Paul Ma, Scottsdale, AZ (US); Mihaela Balseanu, Scottsdale, AZ (US)

(21) Appl. No.: 19/281,939

(22) Filed: Jul. 28, 2025

Related U.S. Application Data
(60) Provisional application No. 63/677,928, filed on Jul. 31, 2024.

(51) Int. Cl. H01L 23/00; H01L 21/56; H01L 23/29; H01L 23/31; H01L 25/065

(52) U.S. Cl. CPC H01L 24/80; H01L 21/56; H01L 23/291; H01L 23/3157; H01L 24/05; H01L 24/08; H01L 25/0657; H01L 2224/05567; H01L 2224/05647; H01L 2224/05657; H01L 2224/08147; H01L 2224/80004; H01L 2224/80007; H01L 2224/80011; H01L 2224/80013; H01L 2224/80014; H01L 2224/80051; H01L 2224/80895; H01L 2224/80896; H01L 2225/06565

(57) ABSTRACT

Various embodiments of the present technology may provide a method for fabricating a semiconductor structure. The method may include receiving a source substrate having a dielectric layer and a conductive feature, selectively depositing a barrier layer only on a top surface of the conductive feature, modifying a top surface of the dielectric layer, and removing the barrier layer after modifying the dielectric layer. The method may also include cleaning a top layer of the dielectric and conductive feature prior to depositing the barrier layer.

### CROSS-REFERENCE TO RELATED APPLICATIONS

This application is a nonprovisional of, and claims priority to and the benefit of, U.S. Provisional Patent Application No. 63/677,928, filed Jul. 31, 2024 and entitled “METHODS AND STRUCTURE FOR HYBRID BONDING,” which is hereby incorporated by reference herein.

### FIELD

The present disclosure generally relates to a method and structure for hybrid bonding. More particularly, the present disclosure relates to a method for forming a semiconductor structure that is to be bonded to another structure using a hybrid bonding technique.

### BACKGROUND

Conventional die-to-wafer bonding techniques may exhibit problems relating to bonding yield, bonding strength, and bond integrity. Such problems may be the result of residue on the surfaces of the structures, difficulty controlling various fabrication steps (such as chemical mechanical polishing), and delamination/cracking of the structures.

### BRIEF SUMMARY

Various embodiments of the present technology may provide a method for fabricating a semiconductor structure. The method may include receiving a source substrate having a dielectric layer and a conductive feature, selectively depositing a barrier layer only on a top surface of the conductive feature, modifying a top surface of the dielectric layer, and removing the barrier layer after modifying the dielectric layer. The method may also include cleaning a top layer of the dielectric and conductive feature prior to depositing the barrier layer.

According to one aspect, A method for fabricating a semiconductor structure, comprises: receiving a first substrate comprising a first dielectric layer and a first conductive feature that is partially embedded within the first dielectric layer; selectively depositing a first barrier layer only on a top surface of the first conductive feature; modifying a top surface of the first dielectric layer; and removing the first barrier layer after modifying the top surface of the first dielectric layer.

In one embodiment, the method further comprises exposing the first substrate to a cleaning process prior to selectively depositing the first barrier layer.

In one embodiment, removing the barrier layer comprises exposing the first substrate to a plasma process.

In one embodiment, modifying the top surface of the first dielectric layer comprises exposing the top surface of the first dielectric to a plasma treatment.

In one embodiment, modifying the top surface of the first dielectric comprises depositing a second dielectric material on the top surface of the first dielectric layer.

In one embodiment, the method further comprises: receiving a second substrate comprising a second dielectric layer and a second conductive feature; selectively depositing a second barrier layer only on a top surface of the second conductive feature; modifying a top surface of the second dielectric layer; removing the second barrier layer after modifying the second dielectric layer; and bonding the second substrate to the first substrate, wherein the first and second conductive features vertically align with each other.

In one embodiment, the method further comprises: exposing the second substrate to the cleaning process, wherein the cleaning process comprises at least one of a thermal, a radical, an atomic, or a plasma process.

In one embodiment, the method further comprises bonding the first substrate to a second substrate, wherein the second substate comprises a second dielectric layer and a second conductive feature, and wherein the first and second conductive features are vertically aligned with each other.

In another aspect, a semiconductor structure comprises: a base substrate, a dielectric layer on a surface of the base substrate and having an exposed top surface; a conductive feature partially embedded within the dielectric layer; and a barrier layer completely covering a top surface of the conductive feature, wherein the barrier layer comprises a selective material that forms only on the conductive feature.

In one embodiment, the dielectric layer comprises a first dielectric material and a second dielectric material that is different from the first dielectric material, wherein the second dielectric material forms the exposed top surface.

In one embodiment, the selective material comprises a polyimide.

In one embodiment, the dielectric layer comprises a dielectric material and a modified layer of the first dielectric, wherein the modified layer forms the exposed top surface.

In one embodiment, the modified layer comprises at least one of a silicon-based oxide, a silicon-based nitride, a silicon-based oxycarbide, a silicon-based carbonitride, or a silicon-based oxynitride.

In one embodiment, the conductive feature comprises at least one of copper or cobalt; and the dielectric layer comprises at least one of a silicon-based oxide, a silicon-based nitride, a silicon-based oxycarbide, a silicon-based carbonitride, or a silicon-based oxynitride.

In one embodiment, the top surface of the conductive feature is recessed below the exposed surface of the dielectric layer.

According to further aspects, a semiconductor structure is provided, the semiconductor structure includes a base substrate topped by a dielectric layer with an exposed surface. The dielectric layer is composed of a first dielectric material overlaid by a second dielectric material, distinct from the first, which forms the exposed surface. A conductive feature is embedded within this dielectric layer and has a top surface, which is entirely covered by a barrier layer. In some embodiments, the conductive feature is made of copper or cobalt, while the dielectric layer comprises materials such as SiOₓ, SiN_{y}, SiOₓC_{y}, SiCₓN_{y}, or SiOₓN_{y}. In some embodiments, the first dielectric material includes materials like SiOₓ, SiN_{y}, SiOₓC_{y}, SiCₓN_{y}, or SiOₓN_{y}, whereas the second dielectric material consists of silicon-based oxides, nitrides, carbides, or oxynitrides. In some embodiments, the barrier layer is a selective material that forms only on the conductive feature and comprises materials such as at least one of a polyimide or a polyamic acid. In some embodiments, the top surface of the conductive feature is recessed below the exposed surface of the dielectric layer, and the top surface of the dielectric layer is planar.

### BRIEF DESCRIPTION OF THE DRAWING FIGURES

A more complete understanding of the present technology may be derived by referring to the detailed description when considered in connection with the following illustrative figures. In the following figures, like reference numbers refer to similar elements and steps throughout the figures.

FIG. 1A to FIG. 1E representatively illustrate a cross-sectional view of a semiconductor structure during steps of a fabrication process in accordance with embodiments of the present technology;

FIG. 2A to FIG. 2E representatively illustrate a cross-sectional view of a semiconductor structure during steps of a fabrication process in accordance with embodiments of the present technology;

FIG. 3A to FIG. 3B representatively illustrate a cross-sectional view of a semiconductor structure during steps of a fabrication process in accordance with embodiments of the present technology;

FIG. 4 representatively illustrates a cross-sectional view of a semiconductor structure during steps of a fabrication process in accordance with embodiments of the present technology;

FIG. 5 representatively illustrates a cross-sectional view of a semiconductor structure during steps of a fabrication process in accordance with embodiments of the present technology;

FIG. 6 is a flow diagram of a fabrication process for the semiconductor structure of FIG. 1A to FIG. 1E in accordance with embodiments of the present technology;

FIG. 7 is a flow diagram of a fabrication process for the semiconductor structure of FIG. 2A to FIG. 2E in accordance with embodiments of the present technology;

FIG. 8 representatively illustrates a system in accordance with embodiments of the present technology;

FIG. 9 representatively illustrates a system in accordance with embodiments of the present technology; and

FIG. 10A to FIG. 10B representatively illustrate a cross-sectional view of a semiconductor structure in accordance with embodiments of the present technology.

### DETAILED DESCRIPTION

The present technology may be described in terms of functional block components and various processing steps. Such functional blocks may be realized by any number of components configured to perform the specified functions and achieve the various results. For example, the present technology may employ various controllers, reaction chambers, vessels, susceptors, and showerheads.

As used herein, the term “atomic layer deposition” (ALD) can refer to a vapor deposition process in which deposition cycles, preferably a plurality of consecutive deposition cycles, are conducted in a process chamber. Typically, during each cycle the precursor is chemisorbed to a deposition surface (e.g., a substrate surface or a previously deposited underlying surface such as material from a previous ALD cycle), forming a monolayer or sub-monolayer that does not readily react with additional precursor (i.e., a self-limiting reaction). Thereafter, if necessary, a reactant (e.g., another precursor or reaction gas) can subsequently be introduced into the process chamber for use in converting the chemisorbed precursor to the desired material on the deposition surface. Typically, this reactant is capable of further reaction with the precursor. Further, purging steps can also be utilized during each cycle to remove excess precursor from the process chamber and/or remove excess reactant and/or reaction byproducts from the process chamber after conversion of the chemisorbed precursor. Further, the term “atomic layer deposition,” as used herein, is also meant to include processes designated by related terms such as, “chemical vapor atomic layer deposition”, “atomic layer epitaxy” (ALE), molecular beam epitaxy (MBE), gas source MBE, or organometallic MBE, and chemical beam epitaxy when performed with alternating pulses of precursor composition(s), reactive gas, and purge (e.g., inert carrier) gas.

As used herein, the term “chemical vapor deposition” (CVD) can refer to any process wherein a substrate is exposed to one or more volatile precursors, which react and/or decompose on a substrate surface to produce a desired deposition.

As used herein, the terms “layer,” “film,” and/or “thin film” can refer to any continuous or non-continuous structures and material deposited by the methods disclosed herein. For example, “layer,” “film,” and/or “thin film” could include 2D materials, nanorods, nanotubes, or nanoparticles or even partial or full molecular layers or partial or full atomic layers or clusters of atoms and/or molecules. “Layer,” “film,” and/or “thin film” can comprise material or a layer with pinholes, but still be at least partially continuous. Further, in this disclosure, any two numbers of a variable can constitute a workable range of the variable, and any ranges indicated can include or exclude the endpoints. Additionally, any values of variables indicated (regardless of whether they are indicated with “about” or not) can refer to precise values or approximate values and include equivalents, and can refer to average, median, representative, majority, or the like. Further, in this disclosure, the terms “including,” “constituted by” and “having” can refer independently to “typically or broadly comprising,” “comprising,” “consisting essentially of,” or “consisting of” in some examples. In this disclosure, any defined meanings do not necessarily exclude ordinary and customary meanings in some examples.

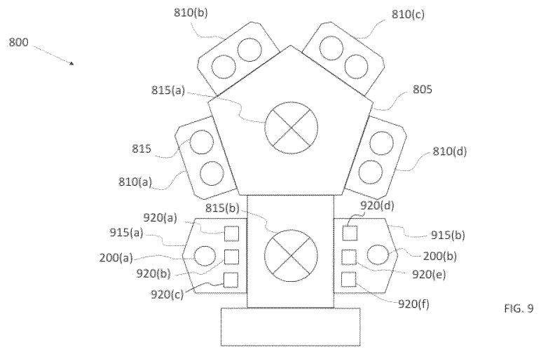

Referring to FIG. 8 and FIG. 9, an exemplary system 800 may comprise a platform module 805 coupled to a plurality of process modules, such as a first process module 810(a), a second process module 810(b), a third process module 810(c), and a fourth process module 810(d). In other embodiments, the system 800 may comprise any number of process modules, and may comprise more than four process modules. In various embodiments, each process module 810 may comprise at least one reaction chamber 812. In an exemplary embodiment, each process module 810 may comprise two reaction chambers 812. Each reaction chamber 812 may be configured to receive a single substrate (e.g., a wafer). The system 800 may further comprise a robot 815 configured to transport the substrate between the various process modules 810.

In various embodiments, each process module 810 (and its respective reaction chamber 812) may be configured to perform a fabrication step from a plurality of fabrication steps. For example, the first process module 810(a) may be configured to perform a cleaning (thermal or plasma) step, the second process module 810(b) may be configured to perform a first thermal atomic layer deposition (ALD) step, the third process module 810(c) may be configured to perform a second thermal ALD step that is different from the first thermal ALD step, and the fourth process module 810(d) may be configured to perform a plasma treatment step. In some examples, a plasma treatment may not include ion bombardment, or may include relatively small amounts of ion bombardment. For example, in some examples the substrate surface may be exposed to plasma, radicals, excited species, and/or atomic species.

In some embodiments, and referring to FIG. 9, the system 800 may be configured as an integrated surface preparation and bonding system. In the present case the system 800 may comprise a bonding system 915, such as a first bonder 915(a) and a second bonder 915(b). In the present embodiment, the bonding system 915 is physically attached to and shares a common platform module 805 with one or more process modules 810. For example, the bonders 915(a), 915(b) may be integrated with various process modules. For example, the integrated process modules may be configured to perform a plasma or thermal cleaning treatment, perform a trim/removal step, an activation step, and/or a wet hydration step to prepare the surfaces for bonding. In some cases, the wet hydration step may be omitted and replaced with a dry (vacuum or atmospheric) step (for example plasma) to prepare the surfaces. Preparing the surfaces of the substrate with either a dry or wet step may improve bonding to the target substrate or to other substrates. In some embodiments, a process module can be configured to performed more than one function, e.g., plasma activation and vacuum based hydration (e.g., plasma, atomic, radical, and/or thermal-OH containing vapor).

In the present case, the system 800 may comprise a first robot 815(a) for moving various substrates to/from the various process modules, and a second robot 815(b) for moving the target wafer and various substrates into the bonders 915(a), 915(b).

In an exemplary embodiment, each bonder 915(a), 915(b) may be configured to bond various substrates, for example source substrates 920(a)˜920(f) to a single target substrate. Each source substrate 920 may be a chiplet, dielet, die, chip, interposer, wafer, or panel. The target substrate 200(a), 200(b) may be a chiplet, dielet, die, chip, interposer, wafer, or panel. In the present case, a single target substrate may be loaded into the first bonder 915(a) and multiple different substrates may be bonded to the single target substrate. The second bonder 915(b) may operate in the same manner. Each bonder 915(a), 915(b) may comprise a robot and associated bond head (not shown) to pick up and place the source substrate on the desired location on the target substrate. In some embodiments, each bonder 915(a), 915(b) may comprise multiple robots and associated bond heads (not shown) to pick up and place multiple substrates simultaneously and/or be configured for specific source substrate types per bond head.

The aforementioned configuration can improve utilization as compared to a linear system whereby each bonder contains one source substrate type and the target substrate is transferred to a multiplicity of bonders. Heterogeneously integrated products may require four or more source substrate types in some embodiments. In other embodiments, six or more source substrate types are required. Using a serial format can greatly impede overall tool utilization with dedicated bonders per source substrate type. The present invention aims to improve utilization as compared to a serial architecture.

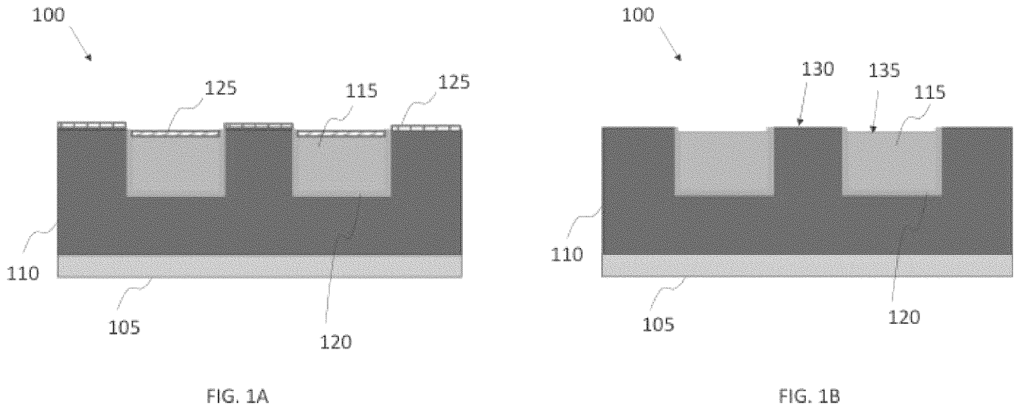

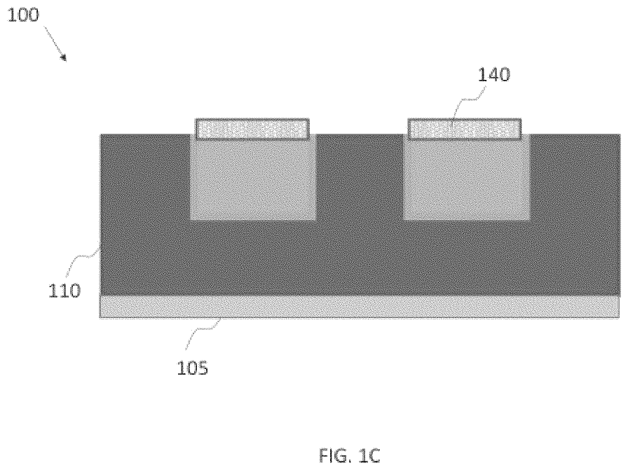

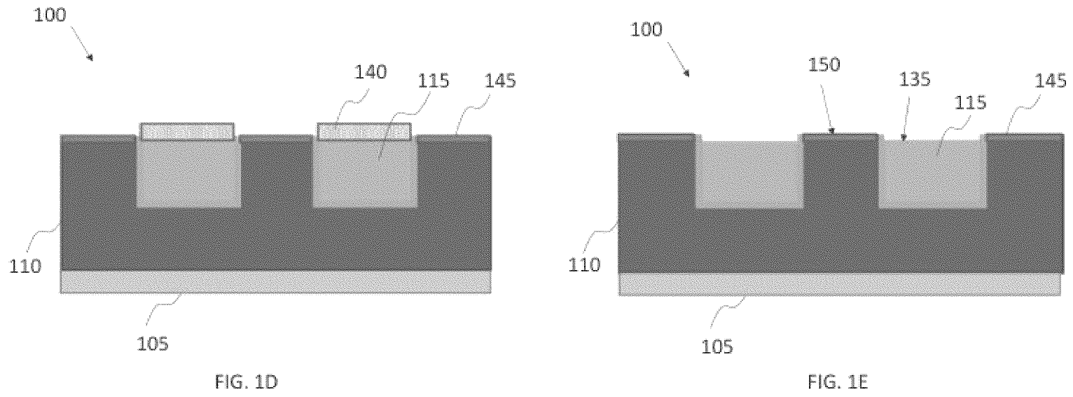

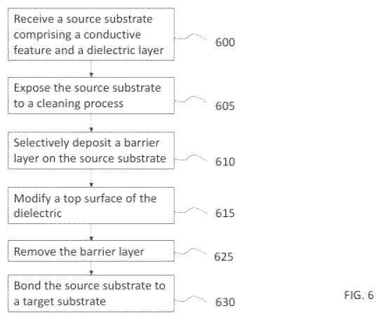

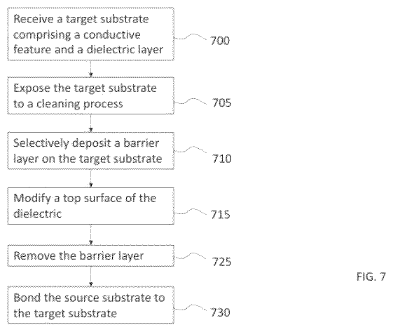

Referring to FIG. 1A to FIG. 1E and FIG. 6, a source substrate 100 may undergo a method comprising a plurality of fabrication steps, wherein the method is performed within and by the system 800. The source substrate 100 may be a chiplet, dielet, die, chip, interposer, wafer, or panel. In an exemplary method, the system 800 may receive the source substrate (600), wherein the source substrate 100 comprises a base substrate 105. In various embodiments, the base substrate 105 may comprise a semiconductor material, such as silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. The base substrate 105 may be doped or undoped. In other cases, the base substrate 105 may comprise interposers comprising silicon, glass, or organic materials. In other cases, the base substrate 105 may comprise a carrier formed from silicon, glass, or ceramic or a tape frame.

In various embodiments, the source substrate 100 may further comprise a dielectric layer 110 overlying the base substrate 105. The dielectric layer 110 may include any suitable material, such as an oxide, a nitride, a carbide, the like, or combinations thereof. In some embodiments, the dielectric layer 110 may comprise a silicon-based oxide, a silicon-based nitride, a silicon-based oxycarbide, a silicon-based carbonitride, or a silicon-based oxynitride. Non-limiting examples include silicon oxide (SiOₓ), silicon nitride (SiNₓ), silicon carbonitride (SiCₓN_{y}), a silicon-based oxycarbide (SiOₓC_{y}), a silicon oxynitride (SiOₓN_{y}), a low-k dielectric material (e.g., a dielectric material having a dielectric constant less than that of silicon oxide, which is about 3.9), the like, or combinations thereof. The dielectric layer 110 may be formed or deposited using at least one suitable deposition technique, such as chemical vapor deposition (CVD), plasma enhanced chemical vapor deposition (PECVD), flowable CVD (FCVD), atomic layer deposition (ALD), spin coating, the like, or combinations thereof.

In various embodiments, the source substrate 100 may further comprise a conductive feature 115 that is partially embedded within the dielectric layer 110, such as within a recess within the dielectric layer 110. For example, a top surface 135 of the conductive feature 115 may be exposed. The top surface 135 may be planar or convex. The conductive feature 115 may comprise any suitable conductive material including Cu, Co, Mo, W, Ni, Al, Ru, Ag, Au, Pt, Ti, Ta, TIN, TaN, the like, or combinations thereof. In the depicted implementations, the conductive feature 115 includes Cu. In some implementations, a conductive layer may be deposited as a blanket layer over the source substrate 100 to fill the recess in the dielectric layer 110 and overlay the top surface 130 of the dielectric layer 110. The conductive layer may be deposited by any suitable deposition technique, such as CVD, ALD, PVD, plating (e.g., electroplating, electroless plating, etc.), the like, or combinations thereof. The conductive layer and any underlying layers (e.g., a liner 120) may then be etched (e.g., by a dry etching, a reactive ion etching (RIE), or a wet etching process) or polished (e.g., by a chemical-mechanical polishing/planarization, or CMP, process) until the top surface 130 of the dielectric layer 110 and the top surface 135 of the conductive feature 115 is exposed, thereby forming the conductive feature 115 in the dielectric layer 110. The conductive feature 115 may be formed as part of a middle-end-of-line (MEOL) process or a back-end-of-line (BEOL) process. For example, the conductive feature 115 may be formed as a bonding pad for coupling the source substrate 100 to another semiconductor structure, die, substrate, or the like, as a portion of a package.

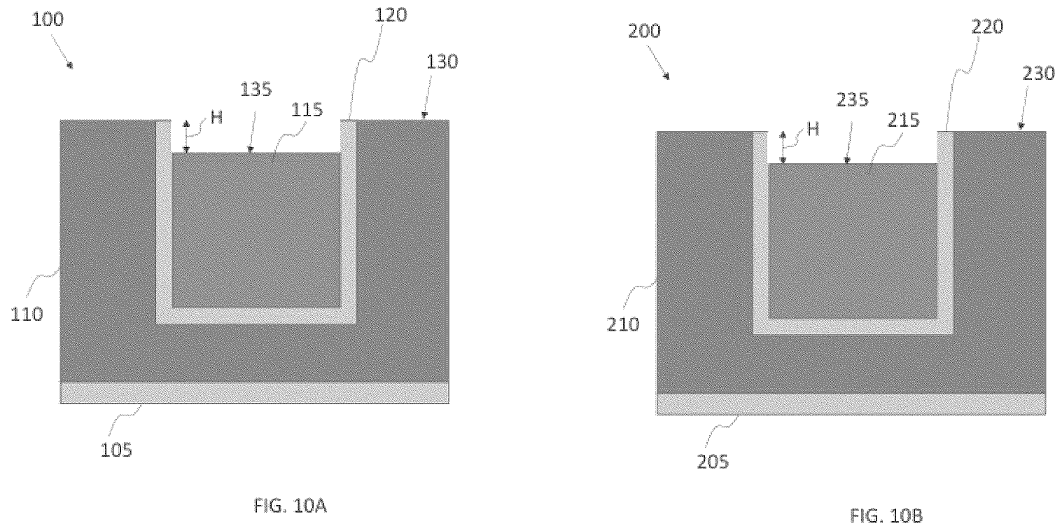

In various embodiments, and referring to FIG. 10A to FIG. 10B, regarding the source substrate, the top surface 135 of the conductive feature 115 may be recessed relative to the top surface 130 of the dielectric layer 110. The top surface 130 of the dielectric layer 110 may be planar. For example, the top surface 135 of the conductive feature 115 may be recessed relative to the dielectric surface 135 by a height H of approximately 5 nm or less. Similarly, and regarding the target substrate, the top surface 235 of the conductive feature 215 may be recessed relative to the top surface 230 of the dielectric layer 210. For example, the top surface 235 of the conductive feature 215 may be recessed relative to the surface 230 by a height H of approximately 5 nm of less.

In various embodiments, and referring back to FIG. 1A to FIG. 1E, the source substrate 100 may further comprise a liner 120 disposed between the conductive feature 115 and the dielectric layer 110. The liner 120 may be configured to reduce or prevent diffusion of metal atoms from the surrounding conductive features (e.g., the subsequently-formed conductive feature 115) into the dielectric layer 110. In some implementations, the liner 120 is formed conformally over the dielectric layer 110, thereby lining a bottom and sidewall surfaces of the recess and over a top surface 130 of the dielectric layer 110. In other cases, the liner 120 is formed selectively within the recess, with the top surface of the dielectric layer 110 capped to prevent deposition. The liner 120 may be deposited by any suitable deposition technique, such as CVD, ALD, physical vapor deposition (PVD), the like, or combinations thereof. In various embodiments, the liner may be formed from Ta or TaN or any other suitable material that is compatible with the material of the conductive feature 115.

In some cases, for example as illustrated in FIG. 1A, the source substrate 100 may further comprise a residue 125 overlying a top surface 130 of the dielectric layer 110 and the top surface 135 of the conductive feature 115. The residue 125 may comprise unwanted metal oxides, organics, ligands, and the like. The residue 125 on the conductive feature 115 may have a different material composition from the residue 125 on the dielectric layer 110. For example, the residue 125 on the conductive feature 115 may contain more oxygen. An exemplary method may further comprise exposing the source substrate to a cleaning process to remove the residue 125 from the surfaces 130, 135 of the source substrate 100 (FIG. 6, step 605), as illustrated in FIG. 1B. In various embodiments, the cleaning process may comprise a thermal, a radical, an atomic and/or a plasma process. In some embodiments, the cleaning process comprises exposing the surfaces 130, 135 to a hydrogen containing gas.

In various embodiments, and referring to FIG. 1C and FIG. 6, the method may further comprise selectively depositing a barrier layer 140 on the top surface 135 of the conductive feature 115 relative to the dielectric layer 110 (FIG. 6, step 610). In other words, the barrier layer 140 is deposited on the top surface 135 of the conductive feature 115 and not on the top surface 130 of the dielectric layer 110. The barrier layer 140 may comprise an organic material that includes a polyimide, a polyamic acid, or other polymeric material, and is etch-resistant as deposited. For example, the barrier layer 140 may be very resistant to various acids, such as HF. In some embodiments, the polyimide-comprising layer comprises primarily polyimide, such as at least about 50% polyimide. In some embodiments, the polyimide-comprising layer consists essentially of polyimide. In some embodiments, polyimide may be deposited at a temperature from about 150° C. to about 200° C., such as from about 170° C. to about 190° C. using 1,6-diaminohexane and pyromellitic dianhydride as precursors for the polymer formation. In some examples, the organic material consists substantially only of polyimide. In some examples, the organic material consists substantially only of amide and polyimide.

Advantageously, selectivity can be achieved without blocking agents on the top surface 130 of the dielectric layer 110; and/or without catalytic agents on the top surface 135 of the conductive feature 115. As a result, in some examples, the dielectric surface 130 does not comprise a passivation or blocking layer, such as a self-assembled monolayer (SAM), which would prevent the actual top surface of the dielectric surface 130 from being exposed to the chemicals of the deposition processes described herein. Thus, in some examples, selectivity is achieved despite the lack of blocking or catalyzing agents, and both conductive and dielectric surfaces 135, 130 are directly exposed to the deposition precursors. Even in material pairs for which selectivity is not perfect, etch-back, or similar corrective treatments using, for example, plasma, may allow selective deposition of organic material.

The deposition process for depositing the barrier layer 140 on the conductive feature 115 may comprise providing a first vapor-phase precursor in the reaction chamber and providing a second vapor-phase precursor in the reaction chamber. The first and second vapor-phase precursors form the organic material selectively on the surface 130 of conductive feature 115 relative to the dielectric surface 135.

In some embodiments, the first vapor-phase precursor may comprise a diamine compound or a triamine compound (e.g., 1,3-diaminopentane (1,3-DAP) or cyclohexane-1,3,5-triamine). The triamine compound may comprise at least three carbon atoms and wherein the amine groups are primary amines. The second vapor-phase precursor may comprise an organic precursor. For example, the second vapor-phase precursor may comprise an anhydride, such as furan-2,5-dione (maleic acid anhydride), dianhydride (e.g., pyromellitic dianhydride (PMDA)), and/or a dianhydride comprising at least one thioanhydride group (e.g., 1,2,4,5-tetrathio-cyclic 1,2:4,5-bis(anhydrosulfide) 1,2,4,5-benzenetetracarboxylic acid (pyromellitic dithioanhydride (PMDTA)).

In other embodiments, the barrier layer 140 may be deposited by providing an acid anhydride and a diamine alternately and sequentially into a reaction chamber to form a polyimide-comprising layer. The polyimide-comprising layer may be selectively deposited on the conductive feature 115 surfaces by providing two precursors, such as a diamine and an acid anhydride, into the reaction chamber alternately and sequentially. In some embodiments a diamine used to deposit the polyimide-comprising layer comprises 1,6-diaminohexane (DAH). In some embodiments the acid anhydride used to deposit the polyimide-comprising layer comprises a dianhydride. In some embodiments the dianhydride is pyromellitic dianhydride (PMDA). In some embodiments the substrate is held at a temperature of greater than about 80° C. or greater than about 170° C. during depositing the polyimide-comprising layer. For example, the polyimide-comprising layer may be deposited at a temperature of about 100° C., about 120° C., about 150° C., about 170° C., about 190° C., about 200° C. or about 220° C. In some embodiments, the polyimide-comprising layer comprises polyamide. In some embodiments the organic polymer that is selectively deposited is a mixture of polyamide, polyimide, and other polymeric material.

The barrier layer 140 may be deposited using a cyclic deposition process, such as an atomic layer deposition (ALD) process, a cyclic chemical vapor deposition (cyclic CVD) process, molecular layer deposition (MLD), or hybrids thereof irrespective of the reaction mechanism. The term “cyclic deposition process” (or sequential deposition) can refer to the sequential introduction of precursor(s) and/or reactant(s) into a reaction chamber to deposit material, such as organic material, for example polyimide or polyamic acid, on a substrate. Cyclic deposition includes processing techniques such as atomic layer deposition (ALD), cyclic chemical vapor deposition (cyclic CVD), and hybrid cyclic deposition processes that include an ALD component and a cyclic CVD component. The process may comprise a purge step between providing precursors into the reaction chamber.

As used herein, the term “purge” may refer to a procedure in which vapor-phase precursors and/or vapor-phase byproducts are removed from the substrate surface for example by evacuating the reaction chamber with a vacuum pump and/or by replacing the gas inside a reaction chamber with an inert or substantially inert gas such as argon or nitrogen. Purging may be effected between two pulses of gases which react with each other. However, purging may be effected between two pulses of gases that do not react with each other. For example, a purge, or purging may be provided between pulses of two precursors. Purging may avoid or at least reduce gas-phase interactions between the two gases reacting with each other. It shall be understood that a purge can be effected either in time or in space, or both. For example, in the case of temporal purges, a purge step can be used e.g., in the temporal sequence of providing a first precursor to a reactor chamber, providing a purge gas to the reactor chamber, and providing a second precursor to the reactor chamber, wherein the substrate on which a layer is deposited does not move. For example, in the case of spatial purges, a purge step can take the following form: moving a substrate from a first location to which a first precursor is continually supplied, through a purge gas curtain, to a second location to which a second precursor is continually supplied.

Purging times may be, for example, from about 0.01 seconds to about 90 seconds(s), or from about 0.05 s to about 80 s, or from about 0.05 s to about 70 s or from about 1 s to about 60 s, or from about 0.05 s to about 50 s or from about 0.5 s to about 40 s, or from about 0.05 s to about 30 s or, or from about 0.05 s to about 20 s, or from about 0.05 s to about 10 s, or between about 1 s and about 7 s, such as 4 s, 5 s, 6 s or 8 s, or any other suitable time period (“about” in this context means plus or minus 5 seconds).

The deposition process may comprise one or more cyclic phases. For example, pulsing of first precursor and second precursor may be repeated. In some examples, the process comprises or one or more acyclic phases. In some examples, the deposition process comprises the continuous flow of at least one precursor. In some examples, a precursor may be continuously provided in the reaction chamber. In such an example, the process comprises a continuous flow of a precursor or a reactant. In some examples, one or more of the precursors and/or reactants are provided in the reaction chamber continuously.

The term “atomic layer deposition” (ALD) can refer to a vapor deposition process in which deposition cycles, such as a plurality of consecutive deposition cycles, are conducted in a reaction chamber. The term atomic layer deposition, as used herein, is also meant to include processes designated by related terms, such as chemical vapor atomic layer deposition, when performed with alternating pulses of precursor(s)/reactant(s), and optional purge gas(es). Generally, for ALD processes, during each cycle, a precursor is introduced to a reaction chamber and is chemisorbed to a deposition surface (e.g., a substrate surface that may include a previously deposited material from a previous ALD cycle or other material), forming about a monolayer or sub-monolayer of material that does not readily react with additional precursor (i.e., a self-limiting reaction). Thereafter, in some cases, another precursor or a reactant may subsequently be introduced into the process chamber for use in converting the chemisorbed precursor to the desired material on the deposition surface. The second precursor or a reactant can be capable of further reaction with the precursor. Purging steps may be utilized during one or more cycles, e.g., during each step of each cycle, to remove any excess precursor from the process chamber and/or remove any excess precursor and/or reaction byproducts from the reaction chamber. Thus, in some examples, the cyclic deposition process comprises purging the reaction chamber after providing a first precursor into the reaction chamber. In some examples, the cyclic deposition process comprises purging the reaction chamber after providing a second precursor into the reaction chamber.

CVD type processes typically involve gas phase reactions between two or more precursors and/or reactants. The precursor(s) and reactant(s) can be provided simultaneously to the reaction space or substrate, or in partially or completely separated pulses. The substrate and/or reaction space can be heated to promote the reaction between the gaseous precursor and/or reactants. In some examples the precursor(s) and reactant(s) are provided until a layer having a desired thickness is deposited. In some examples, cyclic CVD processes can be used with multiple cycles to deposit a thin film having a desired thickness. In cyclic CVD processes, the precursors and/or reactants may be provided to the reaction chamber in pulses that do not overlap, or that partially or completely overlap. In some examples, the first precursor is supplied in pulses, the second precursor supplied in pulses and the reaction chamber is purged between consecutive pulses of first precursor and second precursor.

In various embodiments, and referring to FIG. 1D and FIG. 6, the method may further comprise modifying the top surface 130 of the dielectric layer 110 to create a modified layer 145 (FIG. 6, step 615). In some cases, modifying the dielectric surface 130 may comprise depositing a different dielectric material (for example, SiOₓ, SiNₓ, SiCₓN_{y}, SiOₓC_{y}, SiOₓN_{y} or any other silicon-based oxide, silicon-based nitride, silicon-based oxycarbide, silicon-based carbonitride, or silicon-based oxynitride) on the top surface 130 of the dielectric layer 110. In some embodiments, modifying the dielectric surface may comprise depositing the same dielectric material but of varying dangling bond (DB) density, film density, O, C, N, and/or H content from the dielectric layer 110.

Additionally, or alternatively, modifying the dielectric surface 130 may comprise exposing the dielectric surface to a thermal, atomic, radical, and/or plasma treatment. In some embodiments, modifying the dielectric surface 130 may comprise modifying the dangling bond (DB) density, film density, O, C, N, and/or H content to be different from the bulk dielectric layer 110. In some embodiments, modifying the dielectric surface 130 may comprise modifying the wetting properties of the dielectric surface 130. The aforementioned modifications can improve bonding yield, strength, and/or reliability. In other embodiments, modifying the dielectric surface 130 may comprise etching the dielectric surface 130 using atomic layer etching or cyclic etching to adjust the relative height H of the dielectric surface to the recessed Cu for improved bonding yield, strength, and/or reliability. In some embodiments, modifying the dielectric surface 130 may comprise etching the dielectric surface 130 using atomic layer etching or cyclic etching to improve the RMA roughness of the dielectric surface 130 to improve bonding yield, strength, and/or reliability.

In various embodiments, the modified layer 145 may comprise at least one of a silicon-based oxide, a silicon-based nitride, a silicon-based oxycarbide, a silicon-based carbonitride, or a silicon-based oxynitride.

In various embodiments, and referring to FIG. 1E and FIG. 6, the method may further comprise removing the barrier layer 140 (FIG. 6, step 625). The barrier layer 140 may be removed by, for example, plasma treatment, such as a hydrogen-containing plasma treatment, until the top surface 135 of the conductive feature 115 is exposed.

In some embodiments, the barrier layer 140 may be removed by contacting the substrate with one or more of a vapor phase reducing agent, a vapor phase reactant, or reactive species generated from a plasma.

In some embodiments, the barrier layer 140 may be removed by an etch process. In some examples the etch process may comprise an etch process known in the art, for example a dry etch process such as a plasma etch process. In some examples the etch process may comprise exposing the substrate to hydrogen atoms, hydrogen radicals, hydrogen plasma, or combinations thereof. For example, in some examples the etch process may comprise exposing the substrate to a plasma generated from H2 using a power from about 10 W to about 5000 W, from about 25 W to about 2500 W, from about 50 W to about 500 W, or from about 100 W to about 400 W. In some examples the etch process may comprise exposing the substrate to a plasma generated using a power from about 1 W to about 1000 W, from about 10 W to about 500 W, from about 20 W to about 250 W, or from about 25 W to about 100 W.

In some examples the etch process may comprise exposing the substrate to a plasma. In some examples the plasma may comprise reactive species such as oxygen atoms, oxygen radicals, oxygen plasma, or combinations thereof. In some examples the plasma may also comprise noble gas species in addition to reactive species, for example Ar or He species. In some examples the plasma may comprise noble gas species without reactive species. In some instances, the plasma may comprise other species, for example nitrogen atoms, nitrogen radicals, nitrogen plasma, or combinations thereof. In some examples the etch process may comprise exposing the substrate to an etchant comprising oxygen, for example 03. In some examples the substrate may be exposed to an etchant at a temperature of between about 30° C. and about 500° C., or between about 100° C. and about 400° C. In some examples the etchant may be supplied in one continuous pulse or may be supplied in multiple shorter pulses.

In some examples, the plasma may also comprise noble gas species, for example Ar or He species. In some examples the plasma may consist essentially of noble gas species. In some instances, the plasma may comprise other species, for example nitrogen atoms, nitrogen radicals, nitrogen plasma, or combinations thereof.

In some examples, the substrate may be exposed to an etchant at a temperature of between about 30° C. and about 500° C., preferably between about 100° C. and about 400° C. In some examples, the etchant may be supplied in one continuous pulse or may be supplied in multiple shorter pulses.

In some examples, the etch process may be performed at a substrate temperature of about 20° C. to about 500° C. In some examples, the etch process may be performed at a substrate temperature of about 50° C. to about 300° C. In some examples, the etch process may be performed at a substrate temperature of about 100° C. to about 250° C. In some examples, the etch process may be performed at a substrate temperature of about 125° C. to about 200 C.

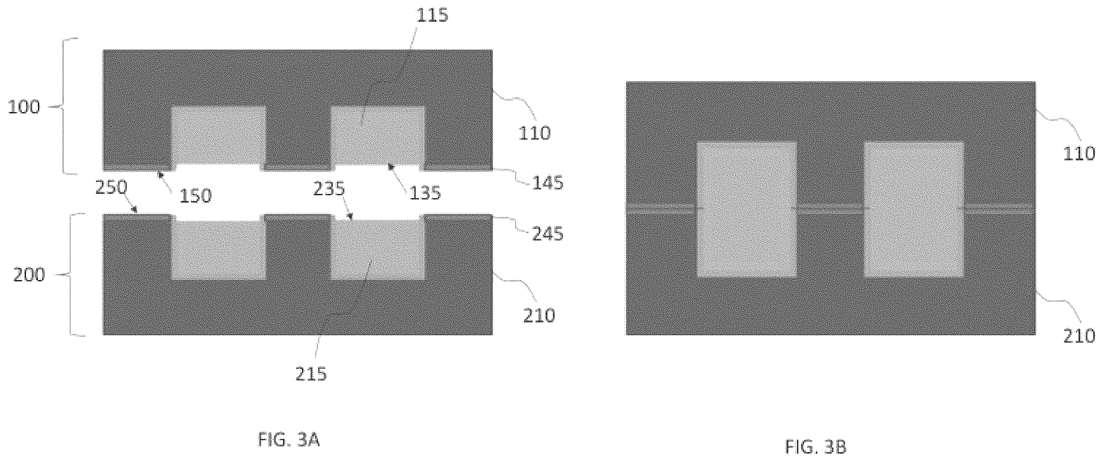

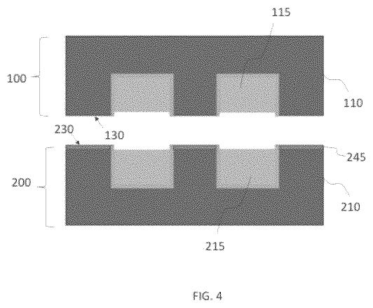

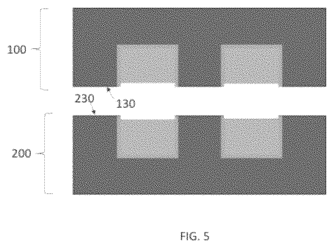

In various embodiments, and referring to FIG. 3A to FIG. 3B and FIG. 6, the method may further comprise bonding the source substrate 100 to a target substrate 200 (FIG. 6, step 630).

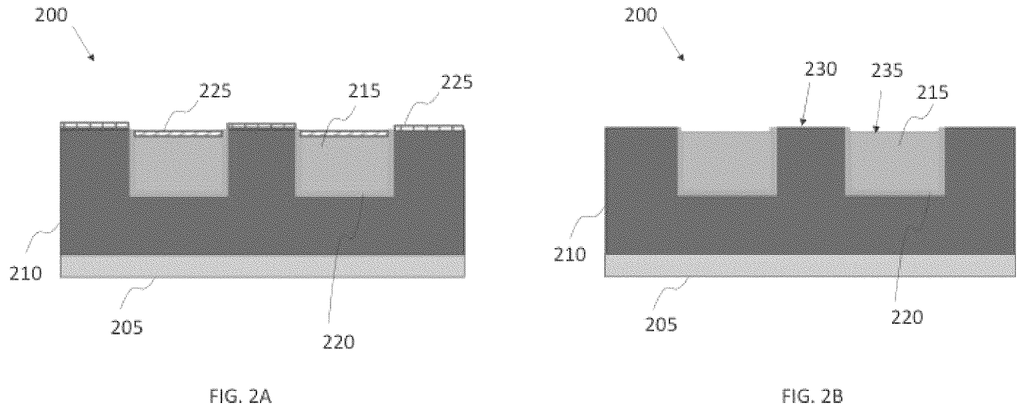

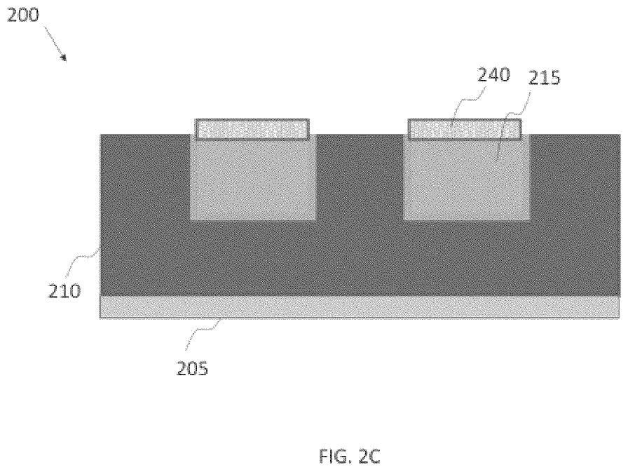

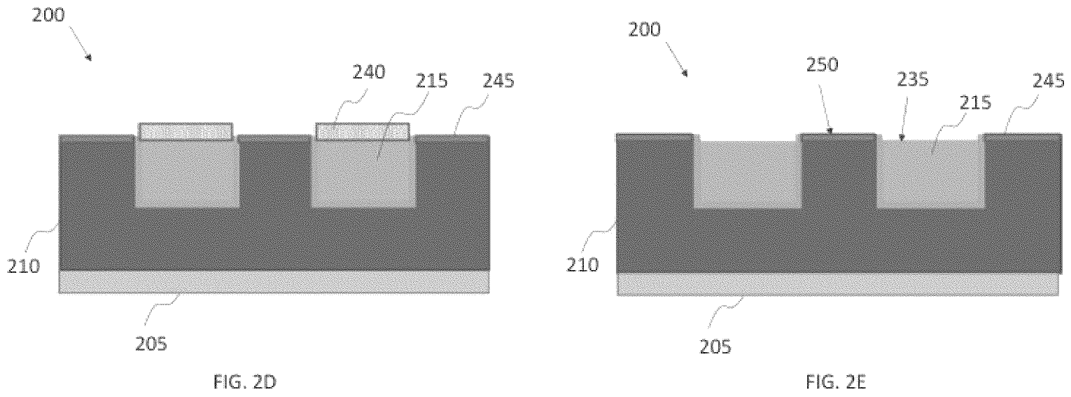

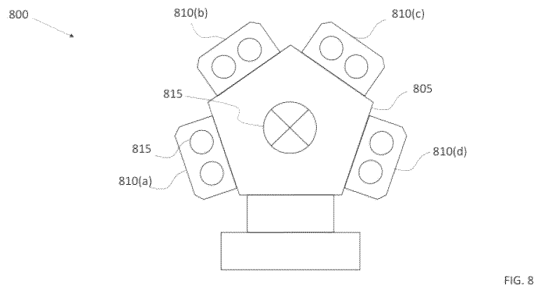

In various embodiments, and referring to FIG. 2A to FIG. 2E and FIG. 7, the target substrate 200 may undergo a similar process as that of the source substrate 100. For example, the system 800 may receive the target substrate 200 (700), wherein the target substrate 200 comprises a dielectric layer 210 overlying a base substrate 205 and a conductive feature 215 embedded within the dielectric layer 210. The dielectric layer 210 and conductive feature 215 may be formed in the same manner as described for the source substrate 100 and may comprise the same materials as the dielectric layer 110 and the conductive feature 115. The target substrate 200 may be a chiplet, dielet, die, chip, interposer, wafer, or panel. Similarly, the base substrate 205 may comprise a semiconductor material, such as silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. The base substrate 205 may be doped or undoped. In other cases, the base substrate 205 may comprise interposers comprising silicon, glass, or organic materials. In other cases, the base substrate 205 may comprise a carrier formed from glass or ceramic, or a tape frame.

The target substrate 200 may then be exposed to a cleaning process (705), such as those described above. Then, a barrier layer 240 may be selectively deposited onto a top surface of the conductive feature 215 (710) in the same or similar manner as described above. The top surface of the dielectric layer 210 may then be modified (715), such as by depositing a different dielectric on the surface or by a thermal, atomic, radical, and/or plasma treatment, to form a modified layer 245. The barrier layer 240 is then removed (725) in the same or similar manner as described above.

In some embodiments, the modified layer 145 of the source substrate 100 may be the same as the modified layer 245 of the target substrate 200. In other embodiments, however, the modified layer 145 of the source substrate 100 may be different from the modified layer 245 of the target substrate 200. For example, the dielectric layer 110 of the source substrate 100 may undergo a plasma treatment, while the dielectric layer 210 of the target substrate 200 may comprise a different dielectric material deposited on the dielectric layer 210 and/or a different treatment type. In some embodiments, the modified dielectric layer of the target substrate 200 comprises a different material than that of the modified dielectric layer of the source substrate 100. For example, modifying the dielectric layer of the target substrate 200 comprises depositing a first material and modifying the dielectric of the source substrate 100 comprises depositing a second material that is different from the first material. In some embodiments, the modified dielectric layer of the target substrate 200 is the same material as the modified dielectric layer of the source substrate 100. In some embodiments, modifying dielectric layer 210comprises subjecting the target substrate 200 to a first treatment and modifying the dielectric layer 110 comprises subjecting the source substrate 100 to a second treatment that is different from the first treatment.

In some embodiments, and referring to FIG. 4, the dielectric layer 130 of the source substrate 100 may not be modified, while the dielectric layer 210 of the target substrate 200 may be modified. In this case, the surface 130 of the dielectric layer 110 is bonded to a surface 230 of the modified layer 245.

In some embodiments, and referring to FIG. 5, neither the source substrate 100 or the target substrate 200 comprise a modified dielectric layer. In this case, the surfaces 130, 230 of the dielectric layers 110, 210 are bonded to each other.

Bonding may comprise flipping the source substrate 100 upside down, such that the exposed surfaces of the conductive feature 115 are facing downward, aligning the conductive feature 115 with the conductive feature 215 of the target substrate, to form the initial for dielectric-to-dielectric bonding. This step can be performed at a low temperature, e.g., at or around room temperature (18C to 25C). The pair may then be heated/annealed (at a higher temperature, such as 150C to 400C) further to form stronger dielectric bonds (e.g., covalent) and induce expansion and bonding of the conductive features 115, 215 to each other. The base substrates 105, 205 may be removed before or after the bonding step. In other cases, the base substrates could remain attached. In other embodiments, the anneal is performed at 150C to 350C. In some embodiments, the anneal is preferably performed at less than 250C.

In various embodiments, each of the fabrication steps 600, 605, 610, 615, and 625 may be performed by a respective process module 810 of the system 800. Similarly, each of the fabrication steps 700, 705, 710, 715, and 725 may be performed by the respective process module 810 of the system 800. In some embodiments, the bonding steps 630, 730 may be performed by the bonding system 915, which may be physically separate from the system 800 or may be attached to the process module 810 (e.g., as illustrated in FIG. 9).

The methods and structures described above may be utilized for hybrid bonding, such as die to wafer hybrid bonding, wafer to wafer hybrid bonding, collective die to wafer hybrid bonding, die to die hybrid bonding, and chip to chip bonding. The bonding in such cases may be permanent.

In addition, the methods and structures described above may be utilized for temporary bonding. In the present case, the base substrate (105 or 205) could be comprised of a carrier (e.g., glass, wafer, ceramic, tape frame) with adhesive or temporary bonding film or film stack comprised of organic, inorganic or a combination of materials. The source substrate 100/target substrate 200 could be temporarily bonded to the carrier with its conductive surface 135/235 protected by the barrier layer 140/240 and optionally, its dielectric surface 125/225 protected by the modified layer 145/245. Similarly, the target substrate 200 could be temporarily bonded to the carrier with its conductive surface 235 protected by the barrier layer 240 and optionally, its dielectric surface 225 protected by the modified layer 245.

In the foregoing description, the technology has been described with reference to specific exemplary embodiments. The particular implementations shown and described are illustrative of the technology and its best mode and are not intended to otherwise limit the scope of the present technology in any way. Indeed, for the sake of brevity, conventional manufacturing, connection, preparation, and other functional aspects of the method and system may not be described in detail. Furthermore, the connecting lines shown in the various figures are intended to represent exemplary functional relationships and/or steps between the various elements. Many alternative or additional functional relationships or physical connections may be present in a practical system.

The technology has been described with reference to specific exemplary embodiments. Various modifications and changes, however, may be made without departing from the scope of the present technology. The description and figures are to be regarded in an illustrative manner, rather than a restrictive one and all such modifications are intended to be included within the scope of the present technology. Accordingly, the scope of the technology should be determined by the generic embodiments described and their legal equivalents rather than by merely the specific examples described above. For example, the steps recited in any method or process embodiment may be executed in any order, unless otherwise expressly specified, and are not limited to the explicit order presented in the specific examples. Additionally, the components and/or elements recited in any apparatus embodiment may be assembled or otherwise operationally configured in a variety of permutations to produce substantially the same result as the present technology and are accordingly not limited to the specific configuration recited in the specific examples.

Benefits, other advantages, and solutions to problems have been described above with regard to particular embodiments. Any benefit, advantage, solution to problems or any element that may cause any particular benefit, advantage, or solution to occur or to become more pronounced, however, is not to be construed as a critical, required, or essential feature or component.

The terms “comprises”, “comprising”, or any variation thereof, are intended to reference a non-exclusive inclusion, such that a process, method, article, composition or apparatus that comprises a list of elements does not include only those elements recited, but may also include other elements not expressly listed or inherent to such process, method, article, composition or apparatus. Other combinations and/or modifications of the above-described structures, arrangements, applications, proportions, elements, materials or components used in the practice of the present technology, in addition to those not specifically recited, may be varied or otherwise particularly adapted to specific environments, manufacturing specifications, design parameters or other operating requirements without departing from the general principles of the same.

The present technology has been described above with reference to an exemplary embodiment. However, changes and modifications may be made to the exemplary embodiment without departing from the scope of the present technology. These and other changes or modifications are intended to be included within the scope of the present technology, as expressed in the following claims.

What is claimed is:

1. A method for fabricating a semiconductor structure, comprising:
receiving a first substrate comprising a first dielectric layer and a first conductive feature that is partially embedded within the first dielectric layer;
selectively depositing a first barrier layer only on a top surface of the first conductive feature;
modifying a top surface of the first dielectric layer; and
removing the first barrier layer after modifying the top surface of the first dielectric layer.

2. The method according to claim 1, further comprising exposing the first substrate to a cleaning process prior to selectively depositing the first barrier layer.

3. The method according to claim 1, wherein removing the first barrier layer comprises exposing the first substrate to a plasma process.

4. The method according to claim 1, wherein modifying the top surface of the first dielectric layer comprises exposing the top surface of the first dielectric layer to a plasma treatment.

5. The method according to claim 1, wherein modifying the top surface of the first dielectric layer comprises depositing a second dielectric material on the top surface of the first dielectric layer.

6. The method according to claim 1, further comprising:
receiving a second substrate comprising a second dielectric layer and a second conductive feature;
selectively depositing a second barrier layer only on a top surface of the second conductive feature;
modifying a top surface of the second dielectric layer;
removing the second barrier layer after modifying the second dielectric layer; and
bonding the second substrate to the first substrate, wherein the first conductive feature and the second conductive feature are vertically aligned with each other.

7. The method according to claim 6, further comprising:
exposing the second substrate to a cleaning process, wherein the cleaning process comprises at least one of a thermal, a radical, an atomic, or a plasma process.

8. The method according to claim 1, further comprising bonding the first substrate to a second substrate, wherein the second substrate comprises a second dielectric layer and a second conductive feature, and wherein the first conductive feature and the second conductive feature are vertically aligned with each other.

9. A semiconductor structure, comprising:
a base substrate;
a dielectric layer on a surface of the base substrate and having an exposed top surface;
a conductive feature partially embedded within the dielectric layer; and
a barrier layer completely covering a top surface of the conductive feature, wherein the barrier layer comprises a selective material that forms only on the conductive feature.

10. The semiconductor structure according to claim 9, wherein the dielectric layer comprises a first dielectric material and a second dielectric material that is different from the first dielectric material, wherein the second dielectric material forms the exposed top surface.

11. The semiconductor structure according to claim 9, wherein the selective material comprises a polyimide.

12. The semiconductor structure according to claim 9, wherein the dielectric layer comprises a dielectric material and a modified layer, wherein the modified layer forms the exposed top surface.

13. The semiconductor structure according to claim 12, wherein the modified layer comprises at least one of a silicon-based oxide, a silicon-based nitride, a silicon-based oxycarbide, a silicon-based carbonitride, or a silicon-based oxynitride.

14. The semiconductor structure according to claim 9, wherein the conductive feature comprises at least one of copper or cobalt; and the dielectric layer comprises at least one of a silicon-based oxide, a silicon-based nitride, a silicon-based oxycarbide, a silicon-based carbonitride, or a silicon-based oxynitride.

15. The semiconductor structure according to claim 9, wherein the top surface of the conductive feature is recessed below an exposed surface of the dielectric layer.

16. A semiconductor structure, comprising:
a base substrate;
a dielectric layer on a surface of the base substrate and having an exposed surface, wherein the dielectric layer comprises a first dielectric material and a second dielectric material, which is different from the first dielectric material, disposed on the first dielectric material, and wherein the second dielectric material forms the exposed surface;
a conductive feature embedded within the dielectric layer and comprising a top surface; and
a barrier layer completely covering a top surface of the conductive feature.

17. The semiconductor structure according to claim 16, wherein the conductive feature comprises at least one of copper or cobalt; and the dielectric layer comprises at least one of SiOₓ, SiN_{y}, SiOₓC_{y}, SiCₓN_{y}, SiOₓN_{y}.

18. The semiconductor structure according to claim 16, wherein the first dielectric material comprises at least one of SiOₓ, SiN_{y}, SiOₓC_{y}, SiCₓN_{y}, SiOₓ N_{y}, and the second dielectric material comprises at least one of a silicon-based oxide, a silicon-based nitride, a silicon-based carbide, or a silicon-based oxynitride.

19. The semiconductor structure according to claim 16, wherein the barrier layer is a selective material that forms only on the conductive feature and comprises at least one of polyimide and polyamic acid.

20. The semiconductor structure according to claim 16, wherein the top surface of the conductive feature is recessed below the exposed surface of the dielectric layer and the top surface of the dielectric layer is planar.
